(19) United States
(12) Patent Application Publication
(10) Pub. No.: US 2024/0147666 A1
(43) Pub. Date: May 2, 2024

(54) THREE-DIMENSIONAL VAPOR CHAMBER DEVICE AND THE METHOD FOR MANUFACTURING THE SAME

(71) Applicant: GUANGZHOU NEOGENE THERMAL MANAGEMENT TECHNOLOGY CO., LTD., GUANGZHOU (CN)

(72) Inventor: JEN-SHYAN CHEN, GUANGZHOU (CN)

(21) Appl. No.: 18/331,086

(22) Filed: Jun. 7, 2023

(30) Foreign Application Priority Data
Oct. 31, 2022 (CN) 202211344089.4
Dec. 21, 2022 (CN) 202223436765.9
Feb. 17, 2023 (CN) 202310139667.9

(51) Int. Cl. H05K 7/20; F28F 1/12

(52) U.S. Cl. CPC H05K 7/20336; F28F 1/12; H05K 7/20318; H05K 7/2039; F28F 2275/00

(57) ABSTRACT

A three-dimensional vapor chamber device includes an upper cover, a bottom cover and a porous wick structure. The upper cover includes a tube and a base plate having a base cavity, an opening hole and an upper outer surface. The tube has a top end having a sealed structure and a tubular cavity, and is configured on the upper outer surface, located above the opening hole and extended outwardly. An airtight cavity is formed from the base cavity and the tubular cavity when the bottom cover is sealed to the upper cover. The porous wick structure is continuously disposed on a tubular internal surface, an upper internal surface and a bottom internal surface. Wherein, the sealed structure is formed by pre-setting a liquid injection port at the top end, injecting the working fluid into the airtight cavity through the liquid injection port, and then sealing the liquid injection port.

### BACKGROUND OF THE INVENTION

### 1. Field of the Invention

The present invention relates to a vapor chamber device and the method for manufacturing the same, and more particularly, to a vapor chamber device for coupling to a liquid-cooling heat dissipator and the method for manufacturing the same.

### 2. Description of the Prior Art

Currently, the performance of electronic products is increasing to meet the growing needs of consumers. The performance of electronic products is greatly influenced by the computing power of chips. Usually, the heat generation of a chip would increase greatly with the computing speed thereof. If the heat generated by the chip cannot be dissipated effectively, it would cause the chip to overheat and then work in the underclocking state or even break down.

A vapor chamber (VC) is a commonly used structure to solve the heat-dissipating problem of chips. Generally, VC is formed by the shape of a flat plate to be configured to solve the problem of heat dissipation in two-dimension. The equivalent heat conductivity of the VC is ten times larger than that of pure copper. The heat generated from the chip can transfer to the whole VC surface, and then to the air through the fins welded on the VC surface. Therefore, the working temperature of the chips can be maintained at a predetermined environmental demand.

Due to the increasing power of the chips, the two-dimensional vapor chamber device cannot meet the requirements of heat dissipation. Therefore, the three-dimensional structure of the vapor chamber device is created. And, the evaporator area and the condenser area of the two-phase flow circulation are configured on different planes to increase the three-dimensional heat-dissipating function.

However, there are still some problems with the three-dimensional vapor chamber device of the prior art. One of the problems is poor circulation to the return water caused by the incomplete continuity of the wick structure between the evaporator area and condenser area; another is depression of the cover plate caused by vacuuming of the vapor chamber; and the other is expansion and deformation of the cover plate when the vapor chamber is heated. The problems above-mentioned will affect the power of the two-phase flow circulation inside the device. Furthermore, the three-dimensional vapor chamber of the prior art requires an additional liquid injection channel from the bottom side of the three-dimensional vapor chamber when the working fluid is injected. However, when the three-dimensional vapor chamber is coupled with a cavity of liquid-cooling heat dissipator, the structure of the liquid injection channel will not ensure the tightness of the liquid-cooling heat dissipator and will cause liquid leakage. In addition, the three-dimensional vapor chamber of the prior art is often configured with heat dissipation fins to increase the heat-dissipating efficiency. Since the heat dissipation fins are mostly riveted or snap-fitted, even if the heat dissipation fins are fixed to the three-dimensional vapor chamber, there will still be a small gap between the heat dissipation fins and the three-dimensional vapor chamber, which will affect the contact area and form thermal resistance to reduce the heat transfer efficiency. If the heat dissipation fins are bonded and fixed to the three-dimensional vapor chamber, the adhesive will increase the thermal resistance to affect the heat transfer efficiency.

### SUMMARY OF THE INVENTION

Therefore, the present invention provides a three-dimensional vapor chamber device and the method for manufacturing the same to solve the problems of the prior art.

The present invention provides a three-dimensional vapor chamber device, which includes an upper cover, a bottom cover, a porous wick structure and a working fluid. The upper cover comprises a base plate and a tube. The base plate has a base cavity, an opening hole, an upper outer surface and an upper internal surface. The tube has a top end, a tubular cavity and a tubular internal surface. The tube is configured on the upper outer surface, located above the opening hole and extended outwardly from the upper outer surface. The top end has a sealed structure. The bottom cover corresponding to the upper cover has a bottom internal surface and a bottom outer surface. An airtight cavity is formed from the base cavity and the tubular cavity when the bottom cover is sealed to the upper cover. The bottom outer surface of the bottom cover is configured to contact a heat source. The porous wick structure is continuously disposed on the tubular internal surface, the upper internal surface and the bottom internal surface. The working fluid is configured in the airtight cavity, and the pressure of the airtight cavity is less than 1 atm. Wherein, the sealed structure is formed by pre-setting a liquid injection port at the top end, injecting the working fluid into the airtight cavity through the liquid injection port, and then sealing the liquid injection port.

Wherein, the liquid injection port is one-piece formed on the top end of the tube, and the tube is one-piece formed on the upper outer surface of the base plate.

Wherein, the bottom cover has a plurality of grooves, and a groove rib is formed between the grooves, the groove rib has a rib surface, and each of the grooves has a groove internal surface and a groove cavity.

Wherein, the porous wick structure is continuously disposed on the upper internal surface, the bottom internal surface, the tubular internal surface, the rib surface of the groove rib and the groove internal surfaces.

Wherein, the three-dimensional vapor chamber device further comprises a plurality of heat dissipation fins, and the tube further comprises a condenser area. The heat dissipation fins are coupled to the condenser area.

Wherein, the porous wick structure is disposed by pre-laying a copper-containing powder on the upper internal surface, the bottom internal surface and the tubular internal surface, and after the heat dissipation fins are disposed on the condenser area of the tube, the porous wick structure is continuously disposed on the tubular internal surface, the upper internal surface and the bottom internal surface and the heat dissipation fins are coupled to the condenser area simultaneously by the same sintering process.

Wherein, the three-dimensional vapor chamber device further comprises a plurality of support columns disposed between the upper internal surface of the base plate and the bottom internal surface of the bottom cover, each of the support columns has a column surface, and the porous wick structure continuously disposed on the upper internal surface, the bottom internal surface, the tubular internal surface and the column surface.

In an embodiment, a three-dimensional vapor chamber device of the present invention comprises a plurality of upper covers, a bottom cover, a porous wick structure and a working fluid. Each of the upper covers comprises a base plate and a tube. The base plate has a base cavity, an opening hole, an upper outer surface and an upper internal surface. The tube has a top end, a tubular cavity and a tubular internal surface. The tube is configured on the upper outer surface and located above the opening hole and extended outwardly from the upper outer surface, and the top end has a sealed structure. The bottom cover has a bottom internal surface and a bottom outer surface. An airtight cavity is formed from the tubular cavity of the each upper covers and the base cavity when the bottom cover is sealed to the upper covers, and the bottom outer surface of the bottom cover is configured to contact a heat source. The porous wick structure is continuously disposed on the tubular internal surface of the each upper covers, the upper internal surface and the corresponding bottom internal surface. The working fluid is configured in the corresponding airtight cavity, and the pressure of the airtight cavity is less than 1 atm. Wherein, the sealed structure is formed by pre-setting a liquid injection port at the top end, and injecting the working fluid into the airtight cavity through the liquid injection port, and then sealing the liquid injection port.

Another scope of the present invention is to provide a method for manufacturing a three-dimensional vapor chamber device, and the method comprises the following steps of:

providing a copper material;

stamping and stretching the copper material to form an upper cover with a three-dimensional structure, the upper cover comprising a base plate, a tube and a liquid injection tube, the base plate having a base cavity, an opening hole, an upper outer surface and an upper internal surface, the tube having a top end, a tubular cavity and a tubular internal surface, the tube located above the opening hole and extended outwardly from the upper outer surface, the liquid injection tube disposed on the top end and having a liquid injection port;

providing a bottom cover matched up with the upper cover and having a bottom outer surface and a bottom internal surface;

providing a plurality of support columns and each of the support columns having a column surface;

forming a porous wick structure on the upper internal surface, the column surface, the tubular internal surface and the bottom internal surface, and providing a plurality of heat dissipation fins to be coupled to a condenser area of the tube;

sealing the upper cover to the bottom cover, and an airtight cavity formed from the base cavity and the tubular cavity, disposing the support columns between the upper internal surface of the upper cover and the bottom internal surface of the bottom cover, the porous wick structure of the upper internal surface, the column surface, the tubular internal surface and the bottom internal surface to be connected to each other; and

providing a working fluid, injecting the working fluid into the airtight cavity through the liquid injection port, and sealing the liquid injection port to form a sealed structure at the top end when the pressure of the airtight cavity is less than 1 atm.

Wherein, the step of forming a porous wick structure on the upper internal surface, the column surface, the tubular internal surface and the bottom internal surface, and providing a plurality of heat dissipation fins, coupled to a condenser area of the tube, further comprises the steps of:

laying a copper-containing powder on the upper internal surface, the column surface, the tubular internal surface and the bottom internal surface, respectively;

providing a plurality of heat dissipation fins to be disposed on the condenser area of the tube; and

sintering the copper-containing powder and the heat dissipation fins for the porous wick structure formed on the upper internal surface, the column surface, the tubular internal surface and the bottom internal surface, and the heat dissipation fins coupled to the condenser area of the tube simultaneously.

In summary, the three-dimensional vapor chamber device in the present invention is capable of forming the sealed structure by creating the liquid injection port at the top end of the tube and directly sealing the liquid injection port, instead of machining an additional liquid injection channel from the bottom cover. Therefore, when the bottom cover of the three-dimensional vapor chamber device is coupled to the cavity of the liquid-cooling heat dissipator, it can form an airtight structure without causing the liquid leakage problem of the liquid-cooling heat dissipator. Moreover, the three-dimensional vapor chamber device of the present invention has a complete and continuous porous wick structure, so the heat energy generated by the heat source can be transferred to the condenser area more quickly, and the liquid working fluid can return to the evaporator area smoothly and quickly, which makes the two-phase flow circulation in the three-dimensional vapor chamber smooth and further enhances the heat-dissipating efficiency. Furthermore, the heat dissipation fins of the three-dimensional vapor chamber device of the present invention can be tightly bonded to the tube by sintering, so as to reduce the heat transfer resistance and further enhance the heat-dissipating efficiency. In addition, the three-dimensional vapor chamber device of the present invention can prevent the bottom cover from being depressed or deformed due to the lower pressure of the airtight cavity through the support column; and the support column also prevents the bottom cover from being uneven due to the expansion of the bottom cover when the three-dimensional vapor chamber device is heated, which prevents the bottom outer surface of the bottom cover from contacting the heat source tightly, and further improves the heat-dissipating efficiency.

### BRIEF DESCRIPTION OF THE APPENDED DRAWINGS

FIG. 1 is a structural schematic diagram illustrating a three-dimensional vapor chamber device according to an embodiment of the present invention.

FIG. 2 is a cross-sectional diagram illustrating a three-dimensional vapor chamber device in FIG. 1.

FIG. 3A and FIG. 3B are structural schematic diagrams illustrating a bottom cover of a three-dimensional vapor chamber device according to an embodiment of the present invention.

FIG. 4 is a cross-sectional diagram illustrating a plurality of heat dissipation fins disposed on outer surface of the tube of the three-dimensional vapor chamber device in FIG. 2.

FIG. 5 is a structural schematic diagram illustrating heat dissipation fins in FIG. 4.

FIG. 6 is a partial enlargement diagram illustrating a support column in FIG. 2.

FIG. 7 is a flowchart diagram illustrating a method for manufacturing a three-dimensional vapor chamber device according to an embodiment of the present invention.

FIG. 8 is a flowchart diagram illustrating a method for manufacturing a three-dimensional vapor chamber device according to an embodiment of the present invention.

FIG. 9 is a cross-sectional diagram illustrating a three-dimensional vapor chamber device according to another embodiment of the present invention.

FIG. 10 is a schematic diagram illustrating the three-dimensional vapor chamber device in FIG. 9 at another viewpoint.

### DETAILED DESCRIPTION OF THE INVENTION

For the sake of the advantages, spirits and features of the present invention can be understood more easily and clearly, the detailed descriptions and discussions will be made later by way of the embodiments and with reference of the diagrams. It is worth noting that these embodiments are merely representative embodiments of the present invention, wherein the specific methods, devices, conditions, materials and the like are not limited to the embodiments of the present invention or corresponding embodiments. Moreover, the devices in the figures are only used to express their corresponding positions and are not drawing according to their actual proportion.

In the description of this specification, the description with reference to the terms “an embodiment”, “another embodiment” or “part of an embodiment” means that a particular feature, structure, material or characteristic described in connection with the embodiment including in at least one embodiment of the present invention. In this specification, the schematic representations of the above terms do not necessarily refer to the same embodiment. Furthermore, the particular features, structures, materials or characteristics described may be combined in any suitable manner in one or more embodiments. Furthermore, the indefinite articles “a” and “an” preceding a device or element of the present invention are not limiting on the quantitative requirement (the number of occurrences) of the device or element. Thus, “a” should be read to include one or at least one, and a device or element in the singular also includes the plural unless the number clearly refers to the singular.

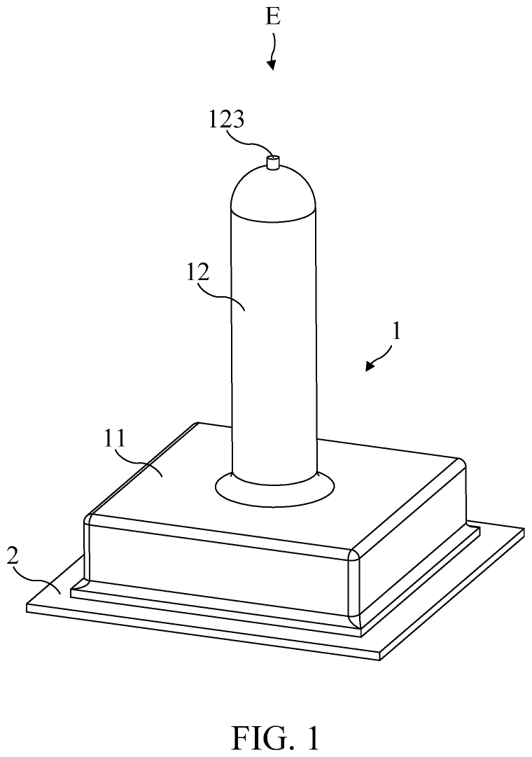

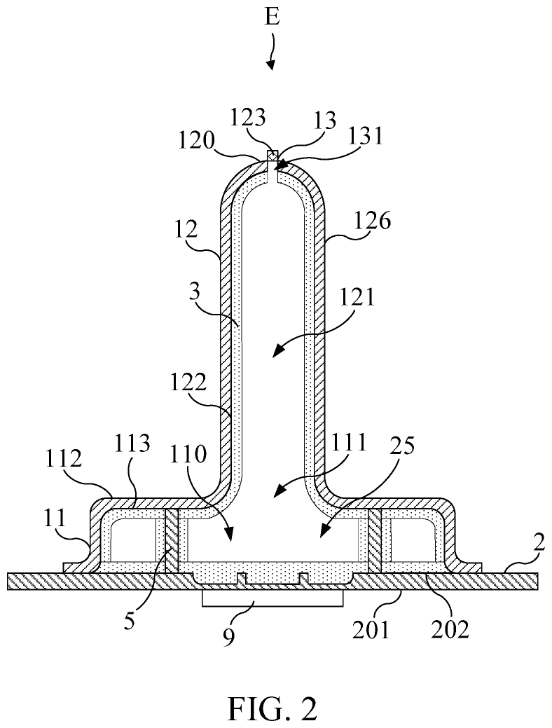

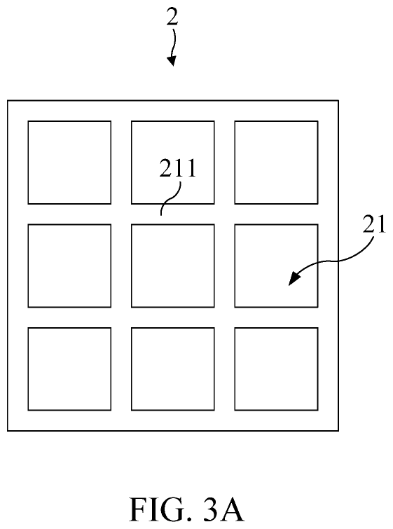

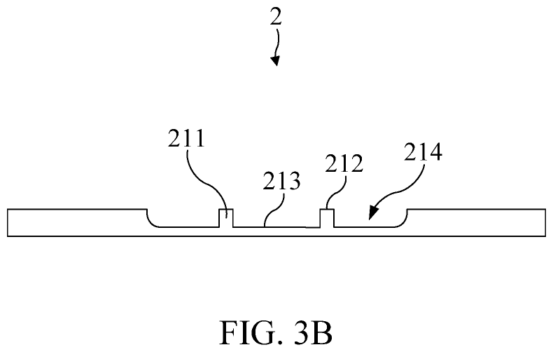

Please refer to FIG. 1, FIG. 2, FIG. 3A and FIG. 3B. FIG. 1 is a structural schematic diagram illustrating a three-dimensional vapor chamber device E according to an embodiment of the present invention. FIG. 2 is a cross-sectional diagram illustrating a three-dimensional vapor chamber device E in FIG. 1. FIG. 3A and FIG. 3B are structural schematic diagrams illustrating a bottom cover 2 of a three-dimensional vapor chamber device E according to an embodiment of the present invention. As shown in FIG. 1 and FIG. 2, in the present embodiment, the three-dimensional vapor chamber device E includes an upper cover 1, a bottom cover 2, a porous wick structure 3 and a working fluid (not shown) and a plurality of support columns 5. The upper cover 1 is corresponding to and matched up with the bottom cover 2. The plurality of support columns 5 are disposed between the upper cover 1 and the bottom cover 2, and the porous wick structure 3 is disposed on the internal surface of the upper cover 1 and the bottom cover 2, and the surface of the plurality of support columns 5. In practice, the upper cover 1 and the bottom cover 2 are in a shape of a circular cover body, class of circular cover bodies and polygonal cover body, but not limited to the above-mentioned. The shape of the upper cover 1 and the bottom cover 2 of the three-dimensional vapor chamber device E can also be designed according to the requirements.

In the present embodiment, the upper cover 1 comprises a base plate 11 and a tube 12. The base plate 11 has a base cavity 110, an opening hole 111, an upper outer surface 112 and an upper internal surface 113. The tube 12 has a top end 120, a tubular cavity 121 and a tubular internal surface 122. The tube 12 is configured on the upper outer surface 112, located above the opening hole 111 and extended outwardly from the upper outer surface 112. The top end 120 of the tube 12 has a sealed structure 123. In practice, the upper cover 1 can be made of copper, but not limited to herein. The upper cover 1 can stamp the base plate 11 to form the base cavity 110, and can stamp and stretch the base plate 11, so the tube 12 is one-piece formed on the upper outer surface 112 and is extended outwardly from the upper outer surface 112, and the opening hole 111 is formed from the recess between the base plate 11 and the tube 12. In another embodiment, the upper cover forms a base cavity by stamping the base plate, the opening hole can be formed in the base plate by processing, and then the tube is configured in the opening hole and can be sealed to the base plate by welding to form the upper cover. In practice, the height of the tube 12 is more than ten times of the thickness of the base plate 11, but is not limited in practice.

In the present embodiment, the upper cover 1 further comprises an liquid injection tube 13 disposed on the top end 120 of the tube 12, and the liquid injection tube 13 has an liquid injection port 131. In practice, after the base plate 11 of the upper cover 1 is continuously stamped to form the base cavity 110 and the tube 12, and the tube 12 can be stamped and stretched, so the liquid injection tube 13 and the liquid injection port 131 are one-piece formed on the top end 120 of the tube 12. At this time, the components of the upper cover 1 are arranged in order from top to bottom as liquid injection port 131, liquid injection tube 13, tube 12 and base plate 11. Furthermore, when the liquid injection port 131 is sealed, the liquid injection port 131 (i.e., the top end 120 of the tube 12) will form a sealed structure 123. In practice, the liquid injection port 131 can be sealed by welding or other means. It is worth noting that the liquid injection tube 13 and the sealed structure 123 of the three-dimensional vapor chamber device E in the present invention are located at the top end 120 of the tube 12, but it is not limited in practice, the liquid injection tube and the sealed structure can also be set at any position on the tube.

As shown in FIG. 2, FIG. 3A and FIG. 3B, in the embodiment, the bottom cover 2 has a bottom internal surface 202 and a bottom outer surface 201. An airtight cavity 25 is formed from the base cavity 110 and the tubular cavity 121 when the bottom cover 2 is sealed to the upper cover 1. The bottom cover 2 has a plurality of grooves 21 disposed on the bottom internal surface 202. Each of the grooves 21 of the bottom cover 2 can correspond to the tube 12 of the upper cover 1, when the bottom cover 2 is sealed to the upper cover 1. A groove rib 211 is formed between each of the two adjacent grooves 21, and all grooves 21 can form at least one groove rib 211, and the groove ribs 211 can be directly or indirectly connected. Further, each of the grooves 21 has a groove internal surface 213 and a groove cavity 214. The airtight cavity 25 is formed from the base cavity 110, the tubular cavity 121 and the groove cavity 214 when the bottom cover 2 is sealed to the upper cover 1. It is worth noting that in the embodiment, the number of the grooves 21 of the bottom cover 2 is 9 and the shape of the grooves 21 is square, but it is not limited in practice. The number and shape of the grooves can be designed according to the requirements.

In the embodiment, the porous wick structure 3 is continuously disposed on the upper internal surface 113 of the base plate 11, the tubular internal surface 122 of the tube 12 and the bottom internal surface 122 of the bottom cover 2. In practice, the porous wick structure 3 can be formed by sintering copper-containing powder or by drying, cracking and sintering slurry. Further, the grooved rib 211 of the bottom cover 2 has a rib surface 212, so the porous wick structure 3 can be continuously disposed on the upper internal surface 113 of the base plate 11, the tubular internal surface 122 of the tube 12, the bottom internal surface 122 of the bottom cover 2, the rib surface 212 of the groove rib 211 and the groove internal surface 213. Since the upper cover 1 of the three-dimensional vapor chamber device E in the present invention is one-piece formed, the porous wick structure 3 can be continuously disposed on the upper internal surface 113 of the base plate 11 and the tubular internal surface 122 of the tube 12 well. Moreover, when the upper cover 1 is sealed to the bottom cover 2, the porous wick structure 3 of the upper cover 1 and the bottom cover 2 can contact each other and fit closely so that the porous wick structure 3 of the entire three-dimensional vapor chamber device E is continuously disposed.

In the embodiment, the working fluid is configured in the airtight cavity 25. The working fluid is one of water, acetone, ammonia, methanol, tetrachloroethane, and hydrofluorocarbon chemical refrigerants. In practice, the working fluid can be injected into the airtight cavity 25 through the liquid injection port 131 of the liquid injection tube 13, and then the air of the airtight cavity 25 is extracted, and finally the liquid injection port 131 is sealed to form the sealed structure 123. When the working fluid is injected into the airtight cavity 25, the working fluid can be attached to the porous wick structure 3. The pressure of the airtight cavity 25 is less than 1 atm. In the embodiment, the bottom outer surface 201 of the bottom cover 2 is configured to contact the heat source 9. In this case, the bottom cover 2 of the three-dimensional vapor chamber device E in the present invention is the evaporator area, and the tube 12 corresponding to the bottom cover 2 is the condenser area 126. It is worth noting that the condenser area 126 can be the top end 120 of the tube 12, or the entire tube 12.

In practice, when the three-dimensional vapor chamber device E operates, the bottom cover 2 (evaporator area) will absorb the heat energy generated by the heat source 9. At this time, the working fluid in the porous wick structure 3 of the bottom internal surface 202, rib surface 212 and groove internal surface 213 of the bottom cover 2 also absorbs heat energy and converts to gaseous working fluid, and the gaseous working fluid flows to the tube cavity 121 of the tube 12. Further, the heat energy in the gaseous working fluid will be transferred to the tube 12 (condenser area 126) for heat dissipation. In addition, the bottom cover 2 comprises the plurality of grooves 21, so the distance between the porous wick structure 3 disposed on the bottom cover 2 and the heat source 9 is shortened, which reduces the thermal resistance of heat transfer from the heat source 9 to the bottom cover 2. Therefore, the three-dimensional vapor chamber device of the present invention has a complete and continuous porous wick structure, so the heat energy generated by the heat source can be transferred to the condenser area more quickly, and the liquid working fluid can return to the evaporator area smoothly and quickly, which makes the two-phase flow circulation in the three-dimensional vapor chamber smooth and further enhances the heat-dissipating efficiency.

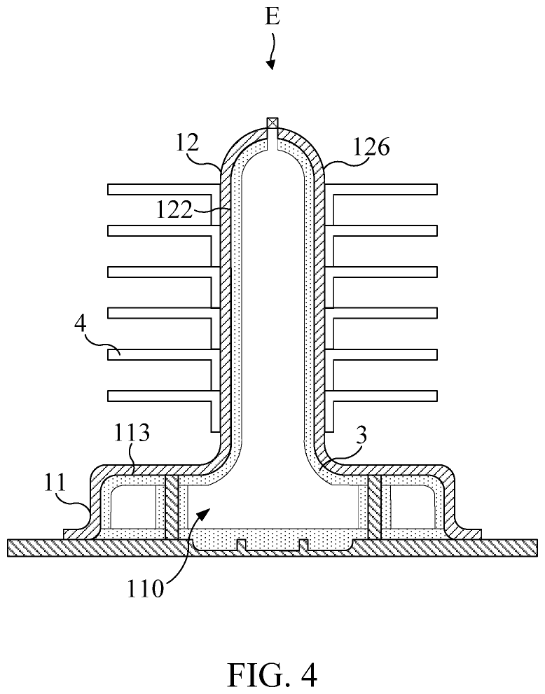

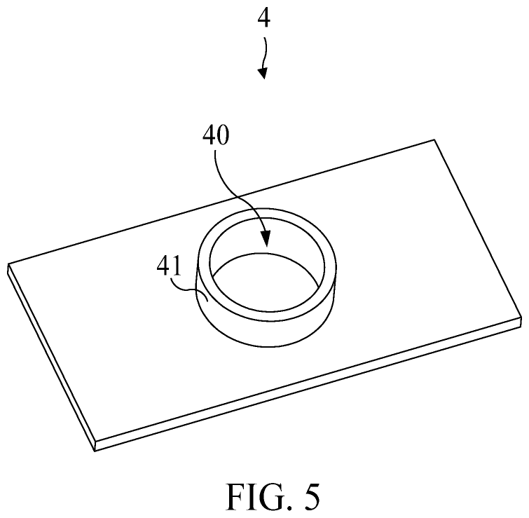

Please refer to FIG. 4 and FIG. 5. FIG. 4 is a cross-sectional diagram illustrating a plurality of heat dissipation fins disposed on outer surface of the tube 12 of the three-dimensional vapor chamber device E in FIG. 2. FIG. 5 is a structural schematic diagram illustrating heat dissipation fins 4 in FIG. 4. As shown in FIG. 4 and FIG. 5, in the embodiment, the three-dimensional vapor chamber device E comprises a plurality of heat dissipation fins 4 disposed on the tube 12. The heat dissipation fins 4 have a hole 40 and a protruding structure 41. The diameter of the hole 40 can be slightly smaller than the diameter of the tube 12, and the protruding structure 41 is positioned around the edges of the hole 40. As shown in FIG. 4, when the plurality of heat dissipation fins 4 are disposed on the tube 12, the protruding structure 41 of the upper heat dissipation fins 4 can hold the lower heat dissipation fins 4, so the plurality of heat dissipation fins 4 can be arranged at a certain spacing. When the heat energy in the gaseous working fluid is transferred to the tube 12, the heat energy can be transferred from the surface of the tube 12 to the heat dissipation fins 4 for heat dissipation. In practice, the number of the heat dissipation fins 4 and the length of the protruding structure 41 can be designed according to the requirements.

In practice, the material of the heat dissipation fins 4 can be copper. After the base plate 11 of the upper cover 1 is continuously stamped to form the base cavity 110 and the tube 12, the heat dissipation fins 4 can be disposed on the tube 12 first, and then the copper-containing powder is laid on the upper internal surface 113 of the base plate 11 and the tubular internal surface 122 of the tube 12 for sintering. During the sintering process, the copper-containing powder can form a porous wick structure3, and the contact positions of the heat dissipation fins 4 and the tube12 can join with each other to reduce the thermal resistance of heat transfer from the tube 12 to the heat dissipation fins 4, so as to enhance the heat dissipation efficiency.

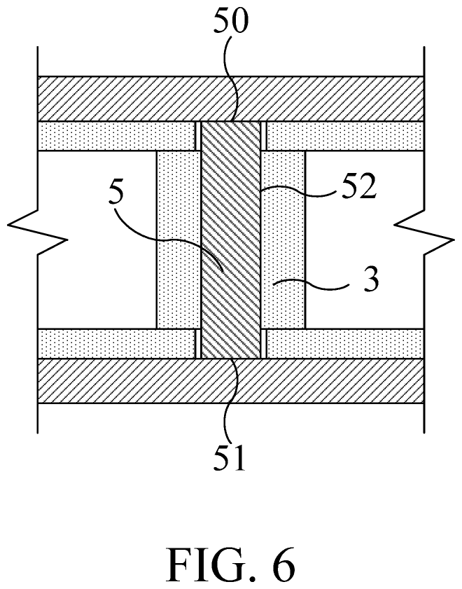

Please refer to FIG. 2 and FIG. 6, FIG. 6 is a partial enlargement diagram illustrating a support column 5 in FIG. 2. As shown in FIG. 2 and FIG. 6, in the embodiment, the three-dimensional vapor chamber device E comprises a plurality of support columns 5 disposed between the upper internal surface 113 of the base plate 11 and the bottom internal surface 202 of the bottom cover 2. Each of the support columns 5 has a column top 50, column bottom 51 and a column surface 52. The column top 50 and the column bottom 51 of the support column 5 can be welded to the upper internal surface 113 of the base plate 11 and the bottom internal surface 202 of the bottom cover 2. Further, the copper-containing powder can also be pre-laid and sintered on the column surface 52. After the copper-containing powder is sintered, the porous wick structure 3 can be continuously disposed on the upper internal surface 113 of the base plate 11, the tubular internal surface 122 of the tube 12, the bottom internal surface 202 of the bottom cover 2, and the column surface 52 of the support column 5. Thus, the porous wick structure 3 located on the column surface 52 can also assist the working fluid to flow back to the bottom cover 2.

It is worth noting that the number of the support columns 5 in FIG. 2 is only two. In practice, the number of the support columns 5 can be determined according to the requirements, the length of the support columns 5 can correspond to the height of the base cavity 110, and the support columns 5 can be encircled around the opening hole 111 of the base plate 11. In addition, the column top 50 and the column bottom 51 of the support column 5 are welded to the upper internal surface 113 of the base plate 11 and the bottom internal surface 202 of the bottom cover 2 respectively. Therefore, when extracting air from the airtight cavity 25, the welded support column 5 can prevent the bottom cover 2 from being depressed or deformed due to the lower pressure of the airtight cavity 25 and also prevent the bottom cover 2 from being uneven due to the expansion of the bottom cover 2 when the three-dimensional vapor chamber device E is heated, which prevents the bottom outer surface 201 of the bottom cover 2 from contacting the heat source 9 tightly, and further improves the heat-dissipating efficiency.

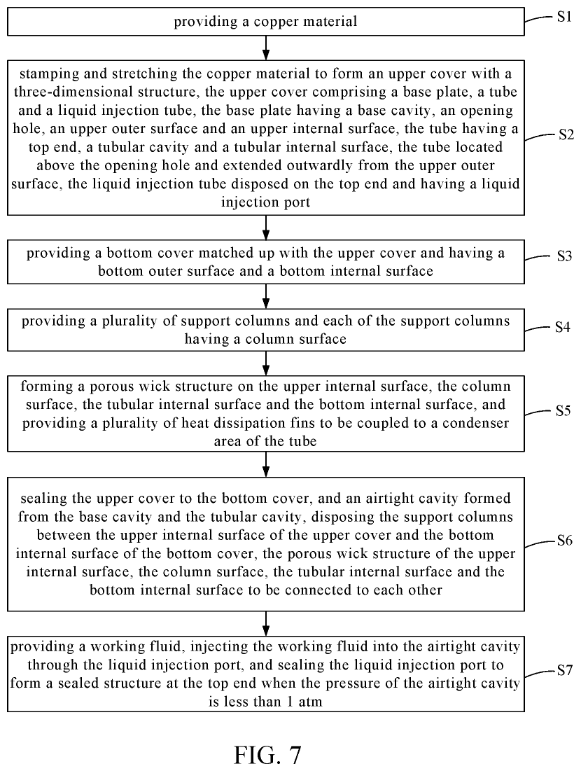

Please refer to FIG. 7. FIG. 7 is a flowchart diagram illustrating a method for manufacturing a three-dimensional vapor chamber device E according to an embodiment of the present invention. The three-dimensional vapor chamber device E shown in FIG. 1 and FIG. 2 can be manufactured through the flowchart diagram in FIG. 7. The method for manufacturing a three-dimensional vapor chamber device E comprises the following steps of:

step S1: providing a copper material (not shown);

step S2: stamping and stretching the copper material to form an upper cover 1 with a three-dimensional structure, the upper cover 1 comprising a base plate 11, a tube 12 and a liquid injection tube 13, the base plate 11 having a base cavity 110, an opening hole 111, an upper outer surface 112 and an upper internal surface 113, the tube 12 having a top end 120, a tubular cavity 121 and a tubular internal surface 122, the tube 12 located above the opening hole 111 and extended outwardly from the upper outer surface 112, the liquid injection tube 13 disposed on the top end 120 of the tube 12 and having a liquid injection port 131;

step S3: providing a bottom cover 2 matched up with the upper cover 1 and having a bottom outer surface 201 and a bottom internal surface 202;

step S4: providing a plurality of support columns 5 and each of the support columns 5 having a column surface 52;

step S5: forming a porous wick structure 3 on the upper internal surface 113, the column surface 52, the tubular internal surface 122 and the bottom internal surface 202, respectively, and providing a plurality of heat dissipation fins 4 to be coupled to the condenser area 126 of the tube 12;

step S6: sealing the upper cover 1 to the bottom cover 2, and an airtight cavity 25 formed from the base cavity 110 and the tubular cavity 121, disposing the support columns 5 between the upper internal surface 113 of the upper cover 1 and the bottom internal surface 202 of the bottom cover 2, the porous wick structure 3 of the upper internal surface 113, the column surface 52, the tubular internal surface 122 and the bottom internal surface 202 to be connected to each other; and

step S7: providing a working fluid, injecting the working fluid into the airtight cavity 25 through the liquid injection port 131, and sealing the liquid injection port 131 to form a sealed structure 123 at the top end 120 when the pressure of the airtight cavity is less than 1 atm. Therefore, the three-dimensional vapor chamber device in the present invention is capable of forming the sealed structure by creating the liquid injection port at the top end of the tube and directly sealing the liquid injection port, instead of machining an additional liquid injection channel from the bottom cover. When the bottom cover of the three-dimensional vapor chamber device is coupled to the cavity of the liquid-cooling heat dissipator, it can form an airtight structure without causing the liquid leakage problem of the liquid-cooling heat dissipator.

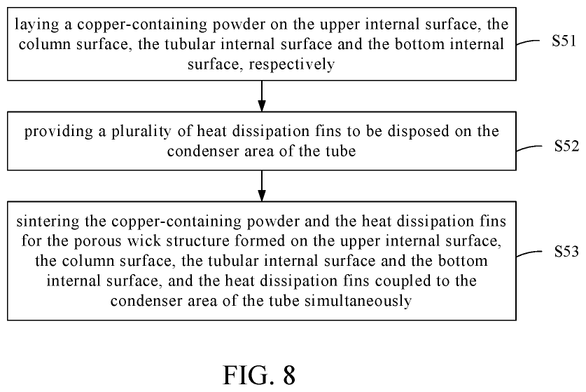

Please refer to FIG. 8. FIG. 8 is a flowchart diagram illustrating a method for manufacturing a three-dimensional vapor chamber device according to an embodiment of the present invention. The step S5 of FIG. 7 further comprises the following steps of:

step S51: laying a copper-containing powder on the upper internal surface 113, the column surface 52, the tubular internal surface 122 and the bottom internal surface 202, respectively;

step S52: providing a plurality of heat dissipation fins 4 to be disposed on the condenser area 126 of the tube 12; and

step S53: sintering the copper-containing powder and the heat dissipation fins 4 for the porous wick structure 3 formed on the upper internal surface 113, the column surface 52, the tubular internal surface 122 and the bottom internal surface 202, and the heat dissipation fins 4 coupled to the condenser area 126 of the tube 12 simultaneously.

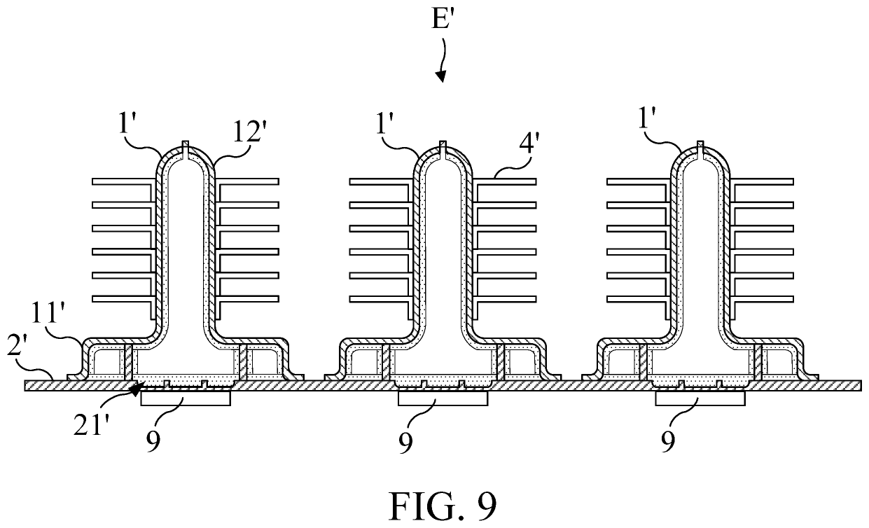

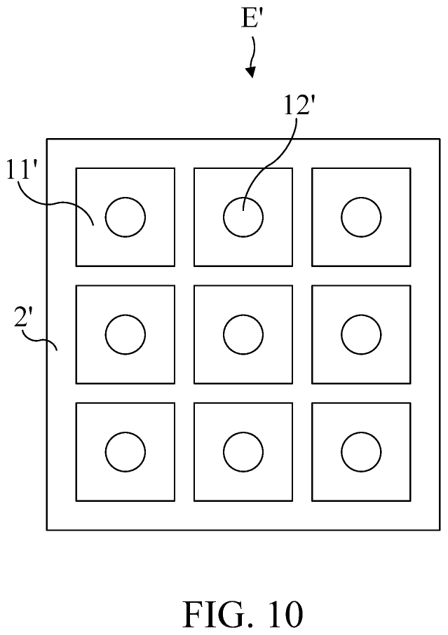

Please refer to FIG. 9 and FIG. 10. FIG. 9 is a cross-sectional diagram illustrating a three-dimensional vapor chamber device E′ according to another embodiment of the present invention. FIG. 10 is a schematic diagram illustrating the three-dimensional vapor chamber device E′ in FIG. 9 at another viewpoint. As shown in FIG. 9 and FIG. 10, the present embodiment differs from the previous embodiment in that the three-dimensional vapor chamber device E′ of the present embodiment comprises a plurality of upper covers 1′ and a bottom cover 2′. In practice, when the bottom cover 2′ contacts a plurality of heat sources 9 at different locations, the plurality of upper covers 1′ can be disposed on the bottom cover 2′ corresponding to the plurality of heat sources 9 to form a plurality of three-dimensional vapor chamber devices for heat dissipation. Furthermore, the heat dissipation fins 4′ can be disposed on each of the upper cover 1′. The structures and functions of the base plate 11′ and the tube 12′ of the upper cover 1′, the porous wick structure, and the support column are substantially the same as those of the corresponding elements in the previous embodiment, and would not be described again herein. In addition, the bottom cover 2′ can also have a plurality of grooves 21′ on the bottom internal surface corresponding the heat source 9 to enhance the heat transfer capability.

In summary, the three-dimensional vapor chamber device in the present invention is capable of forming the sealed structure by creating the liquid injection port at the top end of the tube and directly sealing the liquid injection port, instead of machining an additional liquid injection channel from the bottom cover. Therefore, when the bottom cover of the three-dimensional vapor chamber device is coupled to the cavity of the liquid-cooling heat dissipator, it can form an airtight structure without causing the liquid leakage problem of the liquid-cooling heat dissipator. Moreover, the three-dimensional vapor chamber device of the present invention has a complete and continuous porous wick structure, so the heat energy generated by the heat source can be transferred to the condenser area more quickly, and the liquid working fluid can return to the evaporator area smoothly and quickly, which makes the two-phase flow circulation in the three-dimensional vapor chamber smooth and further enhances the heat-dissipating efficiency. Furthermore, the heat dissipation fins of the three-dimensional vapor chamber device of the present invention can be tightly bonded to the tube by sintering, so as to reduce the heat transfer resistance and further enhance the heat-dissipating efficiency. In addition, the three-dimensional vapor chamber device of the present invention can prevent the bottom cover from being depressed or deformed due to the lower pressure of the airtight cavity through the support column; and the support column also prevents the bottom cover from being uneven due to the expansion of the bottom cover when the three-dimensional vapor chamber device is heated, which prevents the bottom outer surface of the bottom cover from contacting the heat source tightly, and further improves the heat-dissipating efficiency.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A three-dimensional vapor chamber device, comprising:
an upper cover, comprising a base plate and a tube, the base plate having a base cavity, an opening hole, an upper outer surface and an upper internal surface, the tube having a top end, a tubular cavity and a tubular internal surface, the tube being configured on the upper outer surface and located above the opening hole and extended outwardly from the upper outer surface, and the top end having a sealed structure;
a bottom cover, corresponding to the upper cover having a bottom internal surface and a bottom outer surface, an airtight cavity formed from the base cavity and the tubular cavity when the bottom cover is sealed to the upper cover, and the bottom outer surface of the bottom cover configured to contact a heat source;
a porous wick structure, continuously disposed on the tubular internal surface, the upper internal surface and the bottom internal surface; and
a working fluid, configured in the airtight cavity, and the pressure of the airtight cavity less than 1 atm;
wherein, the sealed structure is formed by pre-setting a liquid injection port at the top end, injecting the working fluid into the airtight cavity through the liquid injection port, and then sealing the liquid injection port.

2. The three-dimensional vapor chamber device of claim 1, wherein the liquid injection port is one-piece formed on the top end of the tube, and the tube is one-piece formed on the upper outer surface of the base plate.

3. The three-dimensional vapor chamber device of claim 1, wherein the bottom cover has a plurality of grooves, and a groove rib is formed between the grooves, the groove rib has a rib surface, and each of the grooves has a groove internal surface and a groove cavity.

4. The three-dimensional vapor chamber device of claim 3, wherein the porous wick structure is continuously disposed on the upper internal surface, the bottom internal surface, the tubular internal surface, the rib surface of the groove rib and the groove internal surfaces.

5. The three-dimensional vapor chamber device of claim 1, further comprising a plurality of heat dissipation fins, the tube further comprising a condenser area, and the heat dissipation fins coupled to the condenser area.

6. The three-dimensional vapor chamber device of claim 5, wherein the porous wick structure is disposed by pre-laying a copper-containing powder on the upper internal surface, the bottom internal surface and the tubular internal surface, and after the heat dissipation fins are disposed on the condenser area of the tube, the porous wick structure is continuously disposed on the tubular internal surface, the upper internal surface and the bottom internal surface and the heat dissipation fins are coupled to the condenser area simultaneously by the same sintering process.

7. The three-dimensional vapor chamber device of claim 1, further comprising a plurality of support columns disposed between the upper internal surface of the base plate and the bottom internal surface of the bottom cover, each of the support columns has a column surface, and the porous wick structure continuously disposed on the upper internal surface, the bottom internal surface, the tubular internal surface and the column surface.

8. A three-dimensional vapor chamber device, comprising:
a plurality of upper covers, each of the upper covers comprising a base plate and a tube, the base plate having a base cavity, an opening hole, an upper outer surface and an upper internal surface, the tube having a top end, a tubular cavity and a tubular internal surface, the tube being configured on the upper outer surface and located above the opening hole and extended outwardly from the upper outer surface, and the top end having a sealed structure;
a bottom cover, having a bottom internal surface and a bottom outer surface, an airtight cavity formed from the tubular cavity of the each upper covers and the base cavity when the bottom cover is sealed to the upper covers, and the bottom outer surface of the bottom cover configured to contact a heat source;
a porous wick structure, continuously disposed on the tubular internal surface of the each upper covers, the upper internal surface and the bottom internal surface; and
a working fluid, configured in the airtight cavity, the pressure of the airtight cavity less than 1 atm;
wherein, the sealed structure is formed by pre-setting a liquid injection port at the top end, and injecting the working fluid into the airtight cavity through the liquid injection port, and then sealing the liquid injection port.

9. A method for manufacturing a three-dimensional vapor chamber device, comprising the following steps of:
providing a copper material;
stamping and stretching the copper material to form an upper cover with a three-dimensional structure, the upper cover comprising a base plate, a tube and a liquid injection tube, the base plate having a base cavity, an opening hole, an upper outer surface and an upper internal surface, the tube having a top end, a tubular cavity and a tubular internal surface, the tube located above the opening hole and extended outwardly from the upper outer surface, the liquid injection tube disposed on the top end and having a liquid injection port;
providing a bottom cover matched up with the upper cover and having a bottom outer surface and a bottom internal surface;
providing a plurality of support columns and each of the support columns having a column surface;
forming a porous wick structure on the upper internal surface, the column surface, the tubular internal surface and the bottom internal surface, and providing a plurality of heat dissipation fins to be coupled to a condenser area of the tube;
sealing the upper cover to the bottom cover, and an airtight cavity formed from the base cavity and the tubular cavity, disposing the support columns between the upper internal surface of the upper cover and the bottom internal surface of the bottom cover, the porous wick structure of the upper internal surface, the column surface, the tubular internal surface and the bottom internal surface to be connected to each other; and
providing a working fluid, injecting the working fluid into the airtight cavity through the liquid injection port, and sealing the liquid injection port to form a sealed structure at the top end when the pressure of the airtight cavity is less than 1 atm.

10. The method for manufacturing a three-dimensional vapor chamber device of claim 9, wherein the step of forming a porous wick structure on the upper internal surface, the column surface, the tubular internal surface and the bottom internal surface, and providing a plurality of heat dissipation fins, coupled to a condenser area of the tube, further comprises the steps of:
laying a copper-containing powder on the upper internal surface, the column surface, the tubular internal surface and the bottom internal surface, respectively;
providing a plurality of heat dissipation fins to be disposed on the condenser area of the tube; and
sintering the copper-containing powder and the heat dissipation fins for the porous wick structure formed on the upper internal surface, the column surface, the tubular internal surface and the bottom internal surface, and the heat dissipation fins coupled to the condenser area of the tube simultaneously.
